(19) United States
(12) Patent Application Publication
(10) Pub. No.: US 2014/0102364 A1
(43) Pub. Date: Apr. 17, 2014

(54) COATING APPARATUS

(71) Applicant: NCD Technologies, LLC, Madison, WI (US)

(72) Inventors: Patrick J. Heaney, Middleton, WI (US); Justin Segersten, Madison, WI (US)

(73) Assignee: NCD Technologies, LLC, Madison, WI (US)

(21) Appl. No.: 14/051,169

(22) Filed: Oct. 10, 2013

Related U.S. Application Data
(60) Provisional application No. 61/764,874, filed on Feb. 14, 2013.
(60) Provisional application No. 61/713,327, filed on Oct. 12, 2012.

(51) Int. Cl. C23C 16/27

(52) U.S. Cl. CPC C23C 16/271; C23C 16/27
USPC 118/712; 118/723 R

(57) ABSTRACT

A coating apparatus for applying a film to a substrate is provided. The coating apparatus includes a coating chamber, a filament fixture having a filament array, a tensioning device to maintain tension on the filament array to maintain filaments in a planar array during the application or removal of current or heat to the filaments, and a movable stage arranged to hold the substrate to be treated in the coating apparatus in proximity to the filament array so as to maintain a constant thermal gradient across the substrates being treated in the apparatus. An apparatus for applying nanocrystalline diamond to a substrate is also provided.

### CROSS-REFERENCE TO RELATED APPLICATIONS

This application claims the benefit of and priority to U.S. Provisional Patent Application, Ser. No. 61/713,327, filed Oct. 12, 2012, entitled, APPARATUS FOR APPLYING NANOCRYSTALLINE DIAMOND FILM TO A SUBSTRATE, and claims the benefit of and priority to U.S. Provisional Patent Application, Ser. No. 61/764,874, filed Feb. 14, 2013, entitled THREE-DIMENSIONAL FILAMENT ARRAY FOR APPARATUS FOR APPLYING NANOCRYSTALLINE DIAMOND FILM TO A SUBSTRATE, the contents of each of which are hereby incorporated herein by reference in their entirety.

### FIELD

The present inventions relate to the application of a coating or thin film, such as a nanocrystalline diamond, to a tool or substrate, and in particular to machines, systems, and devices for accomplishing the foregoing.

### BACKGROUND

High-precision machining is used to fabricate miniaturized parts for various uses, such as medical devices, micro-satellites, microfluidics, optics, electronics, micro and nano tools (e.g., micro-end milling), and the like. However, such tools due to their size and the material used are often quick to break or degrade.

To overcome concerns regarding breakage, rapid degradation, tool fatigue and wear, various processes have been developed to coat such tools. For example, such tools may be coated with a diamond coating or thin diamond film.

It is generally difficult to coat a device with diamond. Moreover, no device or apparatus has been able to consistently reproduce these methods on a batch scale to provide batch uniformity.

### SUMMARY

Accordingly, a coating apparatus for applying a film to a substrate is disclosed. The coating apparatus includes a coating chamber, a filament fixture having a filament array, a tensioning device to maintain tension on the filament array so as to maintain filaments in a planar array during the application or removal of heat or current to the filaments, and a stage arranged to hold the substrate to be treated in the coating apparatus in proximity to the filament array.

An assembly for applying a film to a substrate is also disclosed. The assembly includes a filament array having a plurality of filaments coupled to a moveable electrode and a stationary electrode. A tensioning device is coupled to the moveable electrode for movement of the moveable electrode in a linear motion to maintain tension on the filament array and maintain the planar array based upon a variable. A movable stage is also provided, arranged to hold the substrate to be treated in the coating apparatus a distance from the filament array based upon maintaining a constant thermal gradient across the substrates being treated in the apparatus.

An apparatus for applying nanocrystalline diamond to a substrate is also disclosed. The apparatus includes a coating chamber comprising a sealed pressure chamber having an interior cavity. A filament fixture is provided in the interior cavity of the coating chamber and has a filament array, a tensioning device to maintain tension on the filament array, a moveable electrode coupled to the tensioning device and to the filament array, and a stationary electrode coupled to the filament array. A gas inlet is provided on the coating chamber aligned with the filament array such that a gas may be introduced and passed over a filament in the filament array. A movable stage is arranged to hold the substrate to be treated in the apparatus in proximity to the filament array.

A coating apparatus for applying a film to a substrate having a coating chamber and a filament fixture with a three-dimensional filament array is also disclosed. The apparatus also includes a tensioning device to maintain tension on the filament array to maintain filaments in the single planar arrays during the application or removal of heat to the filaments, and a stage arranged to hold the substrate to be treated in the coating apparatus in proximity to the three dimensional filament array.

A moveable stage for the coating apparatus is further disclosed. The moveable stage includes an area for carrying a substrate to be treated in the coating apparatus, and is provided with a means to move the stage and thus the substrate in relative proximity to the filament array so as to maintain optimum processing conditions for the substrate.

Accordingly, a device or apparatus for applying nanocrystalline diamond to a substrate is provided. The apparatus includes a coating chamber, a filament fixture having a filament array, a tensioning device to maintain tension on the filament array, and a movable stage. In the coating apparatus disclosed, various devices are provided which are independently operated or controlled, and may be dynamically controlled to optimize coating or implantation of nanocrystalline diamond on the substrate or more than one substrate uniformly in a batch.

These and other features and advantages of devices, systems, and methods according to this invention are described in, or are apparent from, the following detailed descriptions of various examples of embodiments.

### BRIEF DESCRIPTION OF DRAWINGS

Various examples of embodiments of the systems, devices, and methods according to this invention will be described in detail, with reference to the following figures, wherein:

FIG. 1 is a perspective view of one or more examples of an apparatus for applying a coating, such as a nanocrystalline diamond film, to a substrate, showing a portion of the apparatus separated from the coating chamber.

FIG. 2 is a partial perspective view of one or more examples of a filament fixture and filament array for use with the apparatus shown in FIG. 1.

FIG. 3 is a partial perspective view of one or more examples of a filament array for use with the apparatus shown in FIG. 1, also showing a substrate fixture holder.

FIG. 4 is a partial perspective view of one or more examples of a movable stage for use with the apparatus shown in FIG. 1.

FIG. 5 is top plan view of one or more examples of the filament fixture shown in FIG. 2.

FIG. 6 is an example illustration of the positioning of the movable stage of FIG. 4 carrying a substrate in proximity to a filament array.

FIG. 7 is a partial side elevation view showing one or more examples of embodiments of a three dimensional filament array for use with the apparatus for applying a nanocrystalline diamond shown in FIG. 1.

FIG. 8 is a top plan view of the three dimensional filament array of FIG. 7 for use with the apparatus shown in FIG. 1.

FIG. 9 is a top plan view of one or more alternative examples of embodiments of a three dimensional filament array for use with the apparatus shown in FIG. 1.

It should be understood that the drawings are not necessarily to scale. In certain instances, details that are not necessary to the understanding of the invention or render other details difficult to perceive may have been omitted. It should be understood that the invention is not necessarily limited to the particular embodiments illustrated herein.

### DETAILED DESCRIPTION

An apparatus, machine, device, and/or system is provided and shown in the Figures for coating one or more items or substrates, e.g., tools or more specifically micro or nano tools, medical devices, aerospace devices, as well as other compositions and devices made from compositions of steel, tungsten carbides, titanium, titanium alloys, ceramics, glass, and the like (hereinafter referred to as “substrate” or “substrates”). In particular, the apparatus may be used for coating such items with a coating or thin film, and in one or more particular embodiments, nanocrystalline diamond.

Generally, nanocrystalline diamond refers to a carbon material with crystallite grain sizes ranging from 10 to 100 nm, and may be characterized by electronic bonding character from greater than 50% sp³ (or greater than ½ diamond) up to 98% or 99% sp³ (almost single crystal diamond quality). Nanocrystalline diamond films or coatings may be thin films.

The machine or coating apparatus may be adapted for use with an HFCVD process, that is, a hot filament chemical vapor deposition process, such as a reactor for diamond deposition; and may also be adapted for use in association with a carbon-ion implantation process. While specific examples are provided for purposes of illustration, various methods of coating nanocrystalline diamond or other film on substrates are known and may be accomplished using the systems, methods and devices described herein.

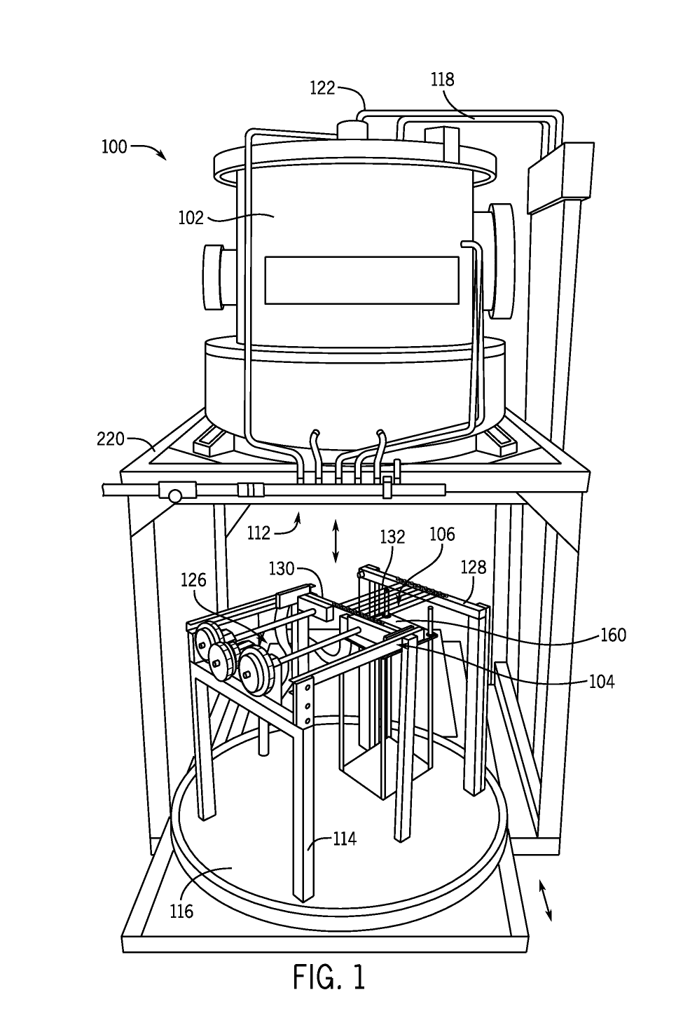

As shown in FIG. 1, the machine or coating apparatus 100 generally includes, among other features, a coating chamber 102, a filament fixture 104 having a filament array 106, and a stage 108 for holding a substrate 110 to be treated. The coating apparatus 100 for purposes of the example described herein may be an HFCVD apparatus used to coat the substrate 110 with a nanocrystalline diamond film.

The coating chamber 102 comprises a sealed pressure chamber formed of suitable non-reactive material. A specific illustrative example of a coating chamber is provided in FIG. 1. However, one of skill in the art will understand that various now know or future developed vacuum or pressure chambers may be used in association with the coating apparatus described herein. In one or more examples of embodiments, the coating chamber 102 includes an interior chamber or cavity 112 with an area containing the filament fixture 104, filament array 106, and stage 108 which carries the substrate 110. In this regard, the filament fixture 104 may be carried by or secured to a portion of the coating chamber 102 so as to support the filament array 106 in proximity to the stage 108. In the illustrated example, the filament array 106 is supported above the stage 108. In one or more further examples, such as illustrated in FIG. 1, the filament fixture 104 includes a support 114 which is supported on the base 116 of the coating chamber 102. In this regard, the base 116 of the coating chamber 102 may be separable and/or securable to the coating chamber to form the chamber or cavity 112 therein. FIG. 1 illustrates a separable base of the coating chamber, however, variations thereon, such as an access panel, a door, a sealable opening, and the like, as well as alternative locations thereof may be acceptable for the purposes provided. In addition, the coating chamber 102 may also include one or more access panels or other sealable or closable apertures. One or more supply lines 118, such as a gas supply or other material supply, may be coupled to or in operable communication with the chamber 102. In one particular example, the coating chamber 102 is carried by a platform 120.

In one or more examples of embodiments, the coating chamber 102 is air tight or sealed, such that a gas may be introduced into the interior or cavity 112 of the chamber. For example, precursor gas (e.g., methane) and hydrogen, (and in some instances Ar) may be mixed and introduced into the chamber 102 through an inlet 122. The inlet 122 may be aligned with the filament array 106, such that the gas may be introduced or passed over the heated filament(s). An outlet 124 may also be provided for removal or venting of off or spent gases. One or more pumps (not shown) may also be included or be coupled to the system, such as a vacuum, vacuum pump assembly or a venting device or assembly, which devices may be used to maintain a desired gas pressure within the chamber 102.

A filament fixture 104 is shown in FIGS. 1-3. As can be seen, the filament fixture 104 has a filament array 106, a tensioning apparatus 126 or device for tensioning the filament array 106, and one or more electrodes 128, 130. The filament fixture 104 and tensioning device 126 may be made of a suitable, durable, non-reactive material capable of withstanding the conditions in the chamber 102. The electrode(s) 128, 130 may be formed of a durable conductive material, capable of withstanding the conditions of the chamber 102 and providing current or voltage sufficient to supply the coupled filaments with same. In one or more examples of embodiments, one or more of said electrodes 128, 130 may be formed of a stainless steel. However, alternative materials suitable for the intended purposes may also be acceptable. A support, namely the filament fixture, is provided for carrying the filament array 106, tensioning apparatus 126, and electrodes 128, 130.

In the illustrated example, first and second electrodes 128, 130 carry or couple, or electrically couple, one or more filaments 132. The electrodes 128, 130 may also physically couple the filaments 132. The first electrode 128 may be a stationary electrode. The second electrode 130 may be a movable electrode. In the alternative, the electrodes may both be movable, or both electrodes may be stationary (in the case of two stationary electrodes an alternative mechanism of tensioning the filaments 132 (as further described herein below) may be provided). The first and second electrodes 128, 130 have one or more devices arranged to couple a filament 132. In the illustrated example, each electrode includes a plurality of spaced apart apertures 134, which apertures may be evenly spaced. The apertures 134 receive a screw, a pin, or other coupling device 136 that may engage the filament 132 and the electrode surface. In one or more examples of embodiments, apertures 134 on the first electrode 128 are aligned with apertures 134 on the second electrode 130 such that the spacing between filaments 132, when a plurality of filaments are secured to the electrodes, is maintained. The first electrode 128 may be coupled to a current source 158 or power source. The second electrode 130 may also be coupled to a current source 158 or power source, which may be the same source or different sources.

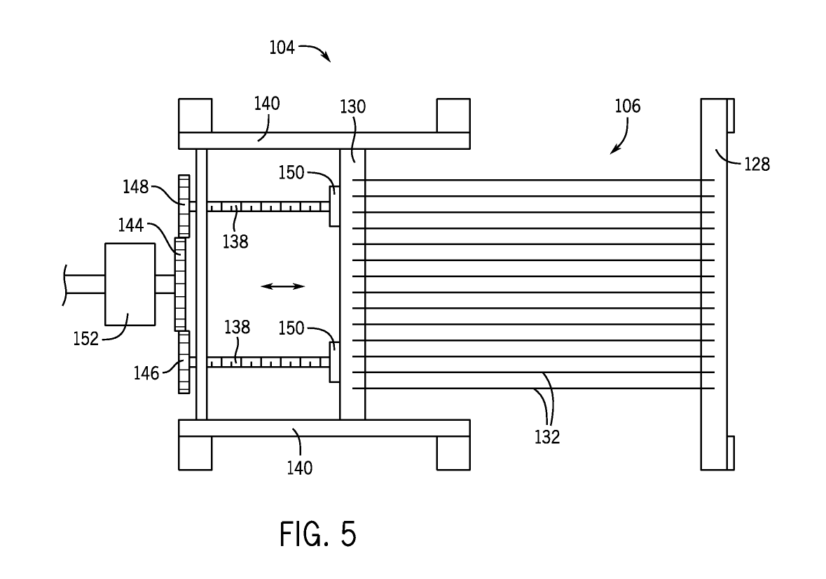

The second electrode, or moveable electrode 130, is coupled to the tensioning apparatus 126. In this regard, the filament fixture 104 also has a tensioning apparatus 126 or device. The tensioning apparatus 126 or device includes one or more arms 138 coupled to the movable electrode to translate the electrode. The electrode 130 may further be carried by, and slidable or movable on, one or more rods or platforms or tracks 140 permitting movement in one plane, such as for example movement in a lateral direction or motion. In the illustrated example, the moveable electrode 130 is mounted on first and second tracks 140. In particular, one or more mounts or carriages or trolleys 142 are mounted and slidable on corresponding tracks 140. The trolleys 142 carry or are mounted to the electrode 130. However, a system and corresponding mechanical components providing additional planes of movement may also be acceptable. The tensioning apparatus 126 has one or more gears 144, 146, 148 operably coupled to the movable electrode, and in particular coupled to the one or more arms 138. In the illustrated examples, the gears include a central gear 144 and two adjacent gears 146, 148 enmeshed with the central gear. The engaged central gear 144 is adapted to rotate the adjacent gears 146 and 148. The adjacent gears 146, 148 are coupled to the one or more arms 138 in a screw-type engagement with a receptor block 150 coupled to the electrode 130. In the example shown in FIG. 5, the meshing gears 144, 146, 148 are coupled to the movable electrode 138 by ball screws, and the moving electrode is carried by sliding support bearings. In one example, the tensioning apparatus 126 may be coupled to the movable electrode 130 by actuating rods held by a bracket assembly. Rotation of the gear 144 results in movement of the actuating rods or arms 138. The rods 138 may move the electrode structure such that tension is applied to the filament(s) 132. In this regard, rotation of gear 144, causes rotation of the arms 138 and turning of the helical screws in the receptor block 150, moving the receptor block and attached electrode 130 in a lateral motion.

In one example of embodiments, the gears 144, 146, 148 and thus the tensioning apparatus 126 are coupled to a rotary feed-through (see FIG. 5) that allows tensioning of the filaments 132. That is, a rotary assembly 152 or arm or rod is coupled to the central gear 144, and may extend through an access opening (not shown) in the chamber 102 to the exterior thereof. The tensioning apparatus 126 or device may be coupled to a manual device for movement of the gear. The tensioning device 126 may also be coupled to an actuating motor, either positioned internal or external to the chamber 102, and therefore may be automated. In either case, the device or motor may be actuated to move the gears and translate the coupled movable electrode to increase or decrease tension on the filaments 132. The tensioning device 126 is continuously movable between an infinite number of positions between a maximum tension and a minimum tension, which may be the result of manufacturing and materials or may be predetermined or preset positions. While one or more specific examples of a tensioning device 126 are described herein, alternative now known or future developed mechanisms for imparting tension on the filaments 132 may be acceptable.

The tensioning device 126 may therefore be a single mechanical source which maintains a precise position of filaments 132 and a consistent thermal gradient across the substrates being treated in the apparatus. In an alternative embodiment, a plurality of such devices may be used. The tensioning device 126 is adapted to continuously tension and relax the filaments 132 in the filament array 106 so as to maintain the array 106 in a plane as the filaments 132 expand and contract. The tensioning device 126 on the filament fixture 104 therefore includes the above described example mechanism (or an alternative thereto) to move filament electrode 130 (or more than one electrode), which is coupled to the filaments 132, in a linear motion. As a result, movement of the electrode 130 changes filament 132 tension. The tensioning device 126 is also capable of dynamic adjustment of the filament 132 tension throughout the coating process. For example, a variable of the coating apparatus 100 may be monitored (such as, but not limited to, filament temperature) and filament tension adjusted in response to the monitored variable. In the alternative, filament tension may be adjusted according to a preset pattern. Preferably, the tensioning device 126 keeps a constant planar array of filaments 132. Dynamic adjustment may be accomplished through automatic or manual means. Accordingly, movement of the movable electrode may be controlled by a controller which receives input from one or more systems or devices as described herein, and communicates instructions to the tensioning device (e.g., a coupled motor) to modify filament tension based upon the input received.

The filament array 106 is carried by the filament fixture 104. In particular, the filament fixture 104 maintains a planar array of filaments 132. The filament array 106 includes a plurality of filaments 132. Each filament 132 is formed of a conductive material or wire. In one or more examples of embodiments, the filament 132 is a tungsten filament. However, alternative materials suitable for the intended purposes may also be acceptable. One or more filaments 132 in the filament array 106 are coupled to the filament fixture 104, and in particular the electrodes 128, 130, by set screws or other devices adapted for accomplishing the same purpose. The filament array 106 includes a plurality of filaments 132 in a spaced apart arrangement, extending from, for example, the stationary electrode 128 to the movable electrode. In one illustrated example, twelve filaments 132 are provided, however, any number of filaments 132 suitable for the intended purposes may be acceptable. The filaments 132 may be arranged in parallel, however, alternative arrangements may be acceptable for manufacturing or other purposes.

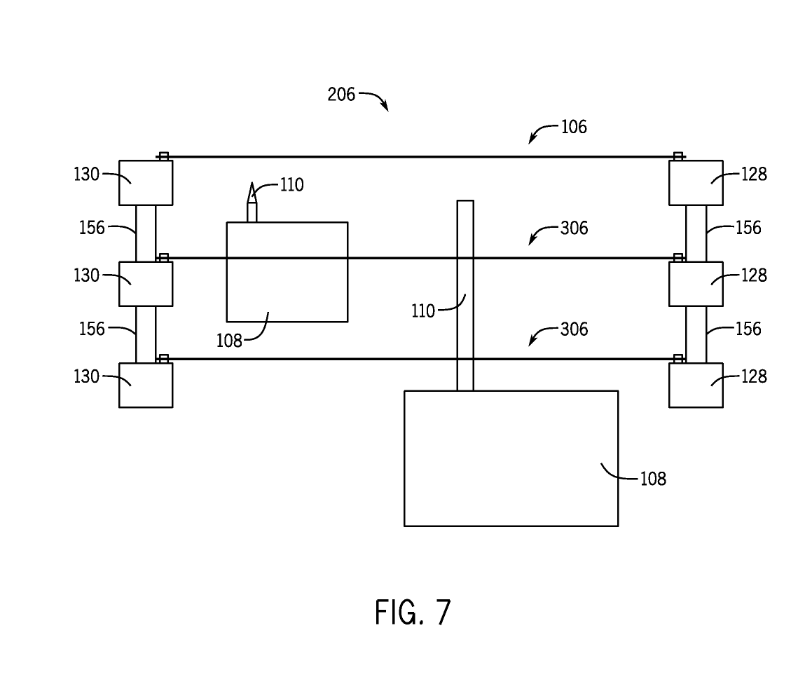

According to one or more alternative examples of embodiments, the filament array may be a three-dimensional (“3d”) array of filaments 132 (see FIGS. 7-9). The 3d filament array 206 may be incorporated into the filament fixture 104. As shown in the illustrated example of FIG. 7, the 3d filament array 206 may include multiple single planar arrays 106, 306 that are positioned in a stacked manner using conductive electrode spacers 156. In the illustrated example, the filament array 106 is provided at the top of the figure, and an illustration of a stage 108 and smaller substrate 110 is shown in reference to said array. Additional filament arrays 306 are spaced and positioned below the above-described array. These additional filament arrays may have the same number, spacing, and arrangement of filaments 132, or in one or more examples of embodiments may have a different number, spacing, and/or arrangement of filaments.

Any one or more, and in one example, all of the filament arrays described herein may include a means by which they can be tightened, such as a tensioning device 126, and may be tightened by the same or separate devices. The tensioning device maintains tension on the filament array(s) to maintain filaments in the single planar arrays, such as may be provided during the application or removal of heat to the filaments.

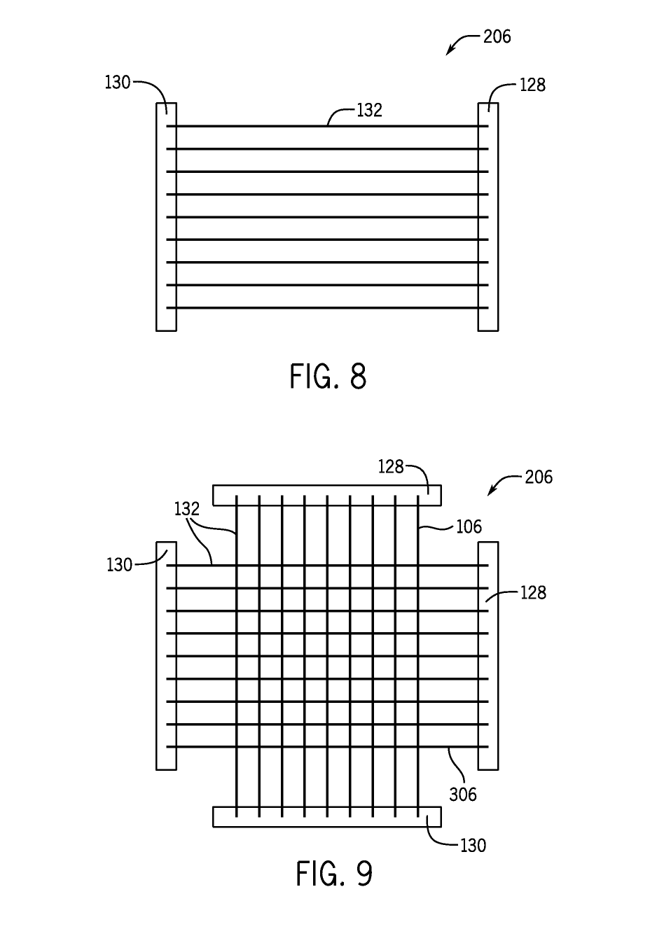

In one or more examples of embodiments, the spacing between filaments 132 and/or filament arrays 106, 306 is adjustable. For instance, spacing may be adjusted between arrays in a 3d array 206 using different length conductive electrode spacers 156 (FIG. 7). Alternative mechanisms for separating filament arrays would also be acceptable. In this regard, the arrays of filaments 132 are adjustable in the y-axis. In addition, filament 132 spacing may be adjusted in the x-axis, on any and/or all of the arrays 106 used (FIG. 8). Filament 132 spacing and filament array 106 spacing is infinitely adjustable. Accordingly, a number of spacing arrangements are allowed which may be optimized for different sized tools/substrates 110 to be coated or treated in the apparatus 100.

As shown in FIG. 9, an array 206 of filaments 132 may be provided in which a first set of filaments or a first planar array 106 are arranged in a first direction on or in a first plane. A second set of filaments or a second planar array 306 may be provided arranged in a second direction on or in a second plane. The second plane 306 may be the same plane as the first plane 106, or the second plane may be separated from the first.

As shown in FIG. 9, the second set of filaments or second plane 306 is arranged perpendicular to the first set of filaments or first plane. However, the direction (e.g., second direction) of the second set of filaments or plane 306 may be infinitely positioned at any position or angle relative to the first set of filaments or plane 106, the perpendicular arrangement shown in FIG. 9 being shown for purposes of example only. The first set and second set of filaments or planes 106, 306 are carried by electrodes 128, 130, such as for example, stainless steel electrodes. Further, filament spacing may be infinitely adjustable across the electrode axis (e.g., the x-axis) for both the first set of filaments or first plane 106 and the second set of filaments or second plane 306. Additional sets of filaments or planes may also be provided in one or more similar or varying orientations.

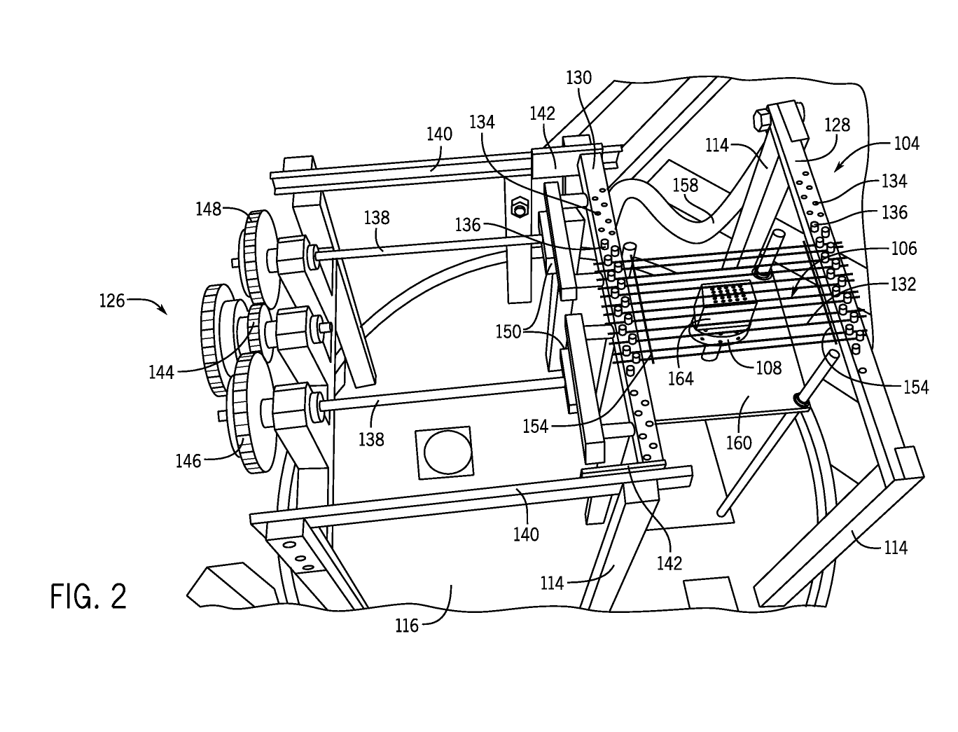

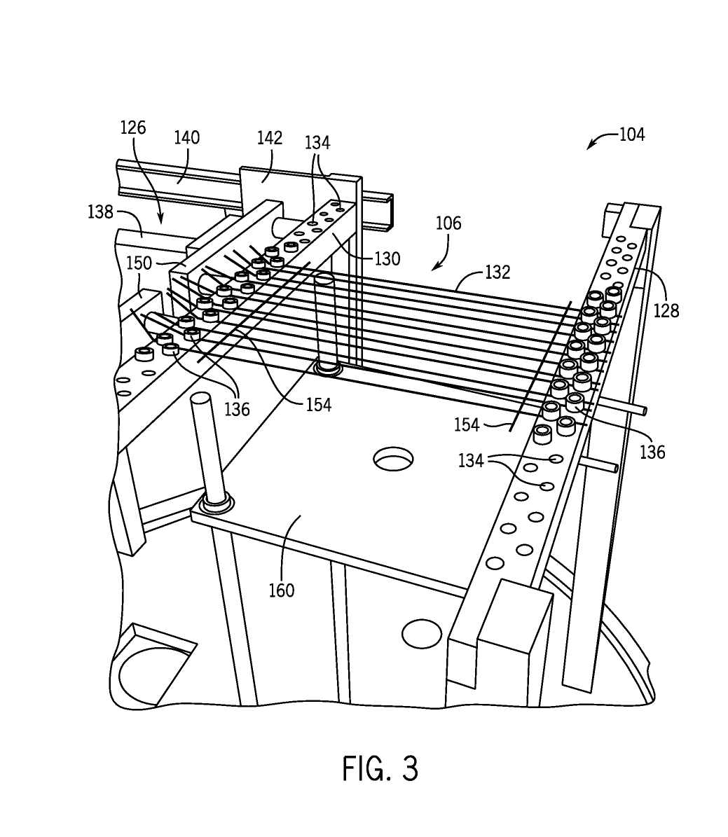

In addition, the filament array 106 may include one or more chute wires 154. The chute wire 154 may be a wire of the same or similar material forming the filaments 132. A chute wire 154 may be provided adjacent an electrode 128 and/or 130. The chute wire 154 intersects one or more filaments 132, and may intersect all said filaments. The chute 154 in the illustrated example is provided perpendicular to the filaments 132 and in proximity to the electrode, although variations thereon may be acceptable for accomplishing the purposes provided. In an alternative example of embodiments, a plurality of chute wires 154 may be provided adjacent each electrode 128, 130. For example, the filament array 106 may include the addition of a stabilizing chute wire 154 at each end of the array. To this end, in the illustrated example of FIGS. 2-3 two chutes are provided. The chute wire 154 is provided to increase the overall stability of the filament array 106, thus resulting in an increase in longevity of the filaments 132.

A current source 158 may be electrically coupled to the filament array 106. The filament fixture 104 may also be coupled to a current source 158 for supplying power to the electrodes 128, 130 and filaments 132. A DC current may be used in one or more examples of embodiments. Alternative power sources or current sources may also be acceptable for the purposes provided. The current source 158 effectively heats the one or more filaments 132 in the filament array 106. Accordingly, in one example of embodiments, a heat source is provided which is resistive heating from an electrical source. In alternative examples of embodiments, it is contemplated that the filament array 106 is provided in association with a heat source. One or more filaments 132, and preferably the filament array 106, may be heated to a predetermined temperature. The current source 158 or heat source may be capable of producing a filament temperature or array temperature of approximately 1800 to 2000 degrees Celsius, or greater, so that the system may regulate the temperature of the substrate 110 in a range of from approximately 700 to 950 degrees Celsius. The filaments in the filament array produce a thermal gradient, which is a result of the heat coming off of the filaments.

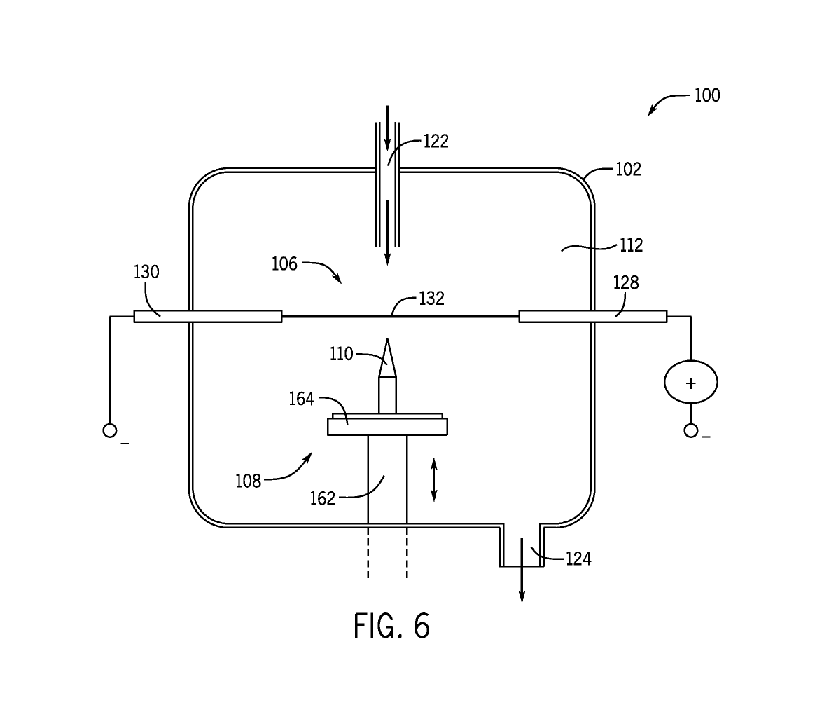

A stage 108 for holding a substrate 110 to be treated may also be provided. In one or more particular examples, a movable stage 108 may be carried in proximity to the filament array 106, an example of which is shown in FIGS. 3 & 4, and in FIGS. 6-7 in which the moveable stage 108 is below the filament array 106. The stage 108 may be formed of a suitable, durable, non-reactive material capable of withstanding the conditions in the chamber 102, and in one or more alternative examples of embodiments may be a durable conductive material capable of withstanding the conditions of the chamber 102 and providing current or voltage. In the illustrated example, the movable stage 108 is also carried by the filament fixture 104. For example, a tool fixture holder or stage holder 160 is positioned on the filament fixture 104. The tool fixture holder 160 is illustrated as a platform having a central aperture, although variations thereon are also contemplated. The central aperture receives a piston 162 or movable rod.

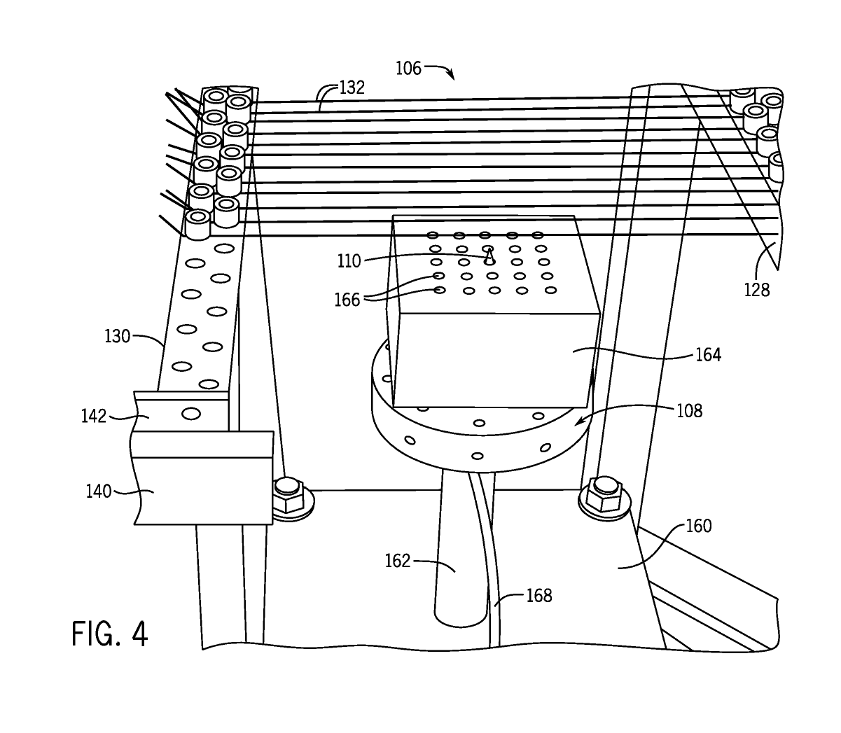

The piston 162 or rod carries the stage 108. The stage 108 has an area for carrying the substrate 110. In particular, the stage 108 may include an area for securing one or more substrates 110 in place for treatment in the coating chamber 102. The area for securing or carrying one or more substrates 110 may be or include a platform or surface. For example, in FIG. 4, a tool or substrate holder 164 or a tool block is provided including a plurality of apertures 166 for holding a plurality of substrates 110. Accordingly, one, or a plurality of slots or apertures 166, may be provided on or in a surface of the stage 108 and/or the surface of the platform or surface. Multiple substrates 110 may be carried by the stage to be treated in batch in the apparatus. In one or more particular examples, the stage 108 or substrate holder statically maintains spacing between adjacent substrates 110. The spacing may be optimized for uniform coating or implantation of the substrate 110. In the alternative, spacing may be optimized to avoid, for instance, arcing. Spacing may also be arranged to align one or more substrates 110 with the filament array 106. The distance or spacing between adjacent substrates 110 may also be dependent upon the size of the substrate 110 being coated. Multiple substrates 110 may be treated on a batch scale with uniformity which is consistently reproducible.

The piston 162 or rod supporting the stage 108 may be coupled to an actuating device for movement thereof in a linear direction. The moveable stage 108 and actuating device are arranged to dynamically position the substrate 110 carried thereby in optimized proximity and/or alignment to the filament array 106. The piston 162 or rod may be continuously moveable to an infinite number of positions between a maximum position and a minimum position which may be the result of manufacturing and materials or may be predetermined or preset positions. In particular, the stage 108 may be moved into proximity to the filament array 106, and/or may be moved away from the filament array. In one particular example, the stage 108 is positioned below the filament array 106 (see FIGS. 6-7). Therefore, the stage 108 is moveable vertically. However, the stage 108 may also be moved laterally to position the stage at a predetermined or optimized position. While the stage 108 is illustrated herein to be positioned below the filament array 106, alternative arrangements and positions would be acceptable for the purposes provided. The stage 108 may be statically movable, in which the stage is moved, positioned, and retained in position relative to the filament array 106. The stage 108 alternatively, or additionally, may be coupled to a manual or a mechanized device for continuous movement thereof. In one or more examples of embodiments, the stage 108 is coupled to a dynamic feedback loop and a mechanized adjustable device in which the stage may continuously or responsively move in accordance with a signal received, such as from a temperature reading, or more specifically a substrate temperature reading. The stage 108 is therefore capable of dynamic adjustment throughout the coating process. For example, a variable of the coating apparatus 100 may be monitored (such as, but not limited to, filament temperature or substrate temperature) and stage height adjusted in response to the monitored variable. In the alternative, the stage 108 may move in accordance with a predetermined plan or pattern. Dynamic adjustment may be accomplished through automatic or manual means. Accordingly, movement of the movable stage may be controlled by a controller which receives input from one or more systems or devices as described herein, and communicates instructions to the movable stage (e.g., a coupled motor) to modify stage height based upon the input received.

The movable stage 108 provides the means to adjust the stage height and thus the distance between the stage 108 and the filament array 106. The movement of the stage 108 can be dynamically adjusted throughout and between processing steps in the coating process. Advantageously, stage height can be adjusted to precisely maintain the temperature of the workpiece or substrate 110 being processed. Also, the stage 108 and substrate(s) 110 can be lowered away from the filament array 106 during the heat up and cool down steps of a coating process, such as the HF-CVD process, which helps to limit further processing at less than optimal temperatures, resulting, for example, in a purer diamond coating during a nanocrystalline diamond coating process. In one or more examples of embodiments, a particular area of a substrate or tool may be targeted for coating in the apparatus. In this regard, the stage may be moved to a position for optimum growth. Accordingly, in addition to the thermal gradient generated by the filaments, the system may calculate other variables such as tool/substrate diameter and mass. The substrate can then be driven up and down via the movable stage to achieve the correct temperature for the part to be coated.

The stage 108 may be coupled to a current source 168. For instance, the stage 108 may be coupled to a pulse generator 168 to apply a voltage or current to the stage or pedestal. In the illustrated example, an input line is coupled to the stage 108 and to a pulse generator to provide pulsed voltage or current to the stage 108. The input line extends to a pulse generator located external to the chamber 102. In one or more alternative examples of embodiments, a continuous current may be applied as opposed to or in addition to a pulsed current.

The stage 108 may also be coupled to a heat source, or may be independently heated, or otherwise arranged to heat the substrate 110. In one or more further examples of embodiments, a substrate heat source may be separately included in the assembly, and positioned proximate the stage 108 which carries the substrate 110 and the filament array 106. The heat source, in one or more examples of embodiments, is capable of supplying heat in the range of approximately 900 degrees Celsius. The heat source may be provided in the interior of the chamber 102.

To obtain a more uniform coating down the substrate, such as for example the shank of a tool, heat may be applied from the bottom of the substrate via a heat source in the stage or substrate holder, to create a thermal gradient in the opposite direction to that generated by the filaments, so as to spread the overall gradient out across the substrate and provide a larger section where the temperature is uniform for a more uniform thickness in coating.

One or more of the foregoing system devices and associated components may be automated. In the coating apparatus 100 disclosed, various devices are provided which are independently operated or controlled, and may be dynamically controlled. Examples of which include, but are not limited to, the pressure of the chamber 102, the gas flow, the temperature of the filaments 132, the tension of the filaments 132, the position of the moveable stage 108, and thus the substrate 110 relative to the filaments 132, the position of substrates 110 relative to each other, and the independent heating of one or more of the stage 108 and/or substrate(s) 110.

In one or more examples of embodiments, a computer or a programmable logic controller, such as a control system, may be coupled to the system for implementing and controlling movement of the tensioning device 126 and/or the movable stage 108. The computer or programmable logic controller may also be coupled to the one or more heat sources or current sources provided so as to control the heat/current sources and, therefore, the temperature within the chamber 102. The computer or programmable logic controller may also be coupled to one or more inlet or outlet ports, or openings, and corresponding pumps or exhaust systems to control flow of gas or other material in the chamber 102.

The computer system or programmable logic controller may be or include a processor. The computers and programmable logic controllers for use with the methods and various components described herein may be programmable computers, which may be special purpose computers or general purpose computers, that execute the system according to the relevant instructions. The computer system or programmable logic controller can be or include an embedded system, a personal computer, notebook computer, tablet computer, server computer, mainframe, networked computer, handheld computer, personal digital assistant, workstation, and the like. Other computer system configurations may also be acceptable including, cell phones, mobile devices, multiprocessor systems, microprocessor-based or programmable electronics, network PC's, minicomputers, and the like. Preferably, the computing system chosen includes a processor suitable in size to efficiently operate one or more of the various systems or functions described herein.

The devices described herein may also be operated or implemented in conjunction with software. To this end, a general purpose software package or a specifically designed software package may be provided. The system, or methods and devices implemented by the system, may be operated by computer-executable instructions, such as but not limited to program modules, executable on a computer. Examples of program modules include, but are not limited to, routines, programs, objects, components, data structures and the like which perform particular tasks or implement particular instructions. The software system may also be operable for supporting the transfer of information within a network.

The system or portions thereof may also be linked to a distributed computing environment, where tasks are performed by remote processing devices that are linked through a communications network. To this end, the system may be configured or linked to multiple computers in a network, including, but not limited to a local area network, a wide area network, a wireless network, and the Internet. Therefore information and data may be transferred within the network or system by wireless means, by hardwire connection or combinations thereof.

The computer or logic controller can also include a display, or other provision for data input and output and communication, etc., such as for example a communication means by which commands may be entered (e.g., a user interface) and content may be displayed (e.g., a graphical user interface) or communicated. Furthermore, the computer or computers or programmable logic controller may be operatively or functionally connected to one or more mass storage devices, such as, but not limited to a database or cloud storage system. The memory storage can be volatile or non-volatile and can include removable storage media. The system may also include computer-readable media which may include any computer readable media or medium that may be used to carry or store desired program code that may be accessed by a computer.

The coating device or machine may also include one or more sensors or other devices for monitoring conditions within the chamber 102 and/or exterior to the chamber, as well as the relevant conditions and parameters of the various devices and operative elements of the coating apparatus 100. For example, one or more sensors may be provided to monitor filament temperature and/or substrate temperature, as well as or in the alternative, to monitor spacing between the filament array 106 and the substrate 110 during the coating process (e.g., a nanocrystalline diamond growth process). In one or more examples of embodiments, an optical pyrometer may be used, or alternatively, a thermocouple embedded in the substrate or sample holder 164, or stage 108, may be used. The one or more sensors may be coupled to the computer or programmable logic controller which receives the signals or data output from the sensors. The computer or programmable logic controller may store and/or display such data, and/or may implement or engage or adjust other connected devices in the system responsive to said data or signals.

The coating apparatus disclosed and claimed herein provides various advantages over existing devices and systems. In particular, the apparatus includes various devices which are independently operated or controlled, and may be dynamically controlled to optimize coating or implantation of a coating, such as a nanocrystalline diamond, on the substrate or more than one substrate uniformly in a batch. For example, the filament fixture has the capacity to move one of the two filament electrodes (or more than one electrode) in a linear motion, allowing dynamic adjustment of the filament tension throughout a nanocrystalline diamond coating process. The advantage of being able to adjust the filament tension throughout the process is twofold. First, having the ability to relax the tension when the process is complete preserves the filaments for further use. Second, having the ability to maintain constant tension on the filament array after they have reached full power, allows for a consistently planar array of filaments. This is important because the thermal gradient generated by the filaments heats the substrate(s) to the required temperature for diamond growth. When there is an array of or plurality of substrates being coated with a thin diamond film, there must be a consistent thermal gradient across all of the tools for uniform consistent growth, which can be achieved with a planar array of filaments. Moreover, the movable stage can be dynamically adjusted throughout and between processing steps in the nanocrystalline diamond coating process. As a result, stage height, and thus substrate position, can be adjusted to precisely maintain the temperature of the workpiece or substrate being processed. In addition, the stage and substrate(s) can be lowered away from the filament array during the heat up and cool down steps of a coating process, which helps to limit further processing at less than optimal temperatures, resulting in a purer diamond coating.

In addition to the foregoing advantages, the apparatus is capable of use with a 3d filament array. The 3d filament array enhances the ability to uniformly coat larger diameter and longer tooling or substrates (see FIG. 7, showing comparison of a small substrate and a larger diameter, longer substrate). Additionally, by adding a chute wire at each end of the array, the individual filament and chute wires become part of a weave that has some of the beneficial characteristics of a mesh or screen, but avoids the problems that arise when a mesh or screen is used in lieu of individual filaments.

As utilized herein, the terms “approximately,” “about,” “substantially”, and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the invention as recited in the appended claims.

It should be noted that references to relative positions (e.g., “top” and “bottom”) in this description are merely used to identify various elements as are oriented in the Figures. It should be recognized that the orientation of particular components may vary greatly depending on the application in which they are used.

For the purpose of this disclosure, the term “coupled” means the joining of two members directly or indirectly to one another. Such joining may be stationary in nature or moveable in nature. Such joining may be achieved with the two members or the two members and any additional intermediate members being integrally formed as a single unitary body with one another or with the two members or the two members and any additional intermediate members being attached to one another. Such joining may be permanent in nature or may be removable or releasable in nature.

It is also important to note that the construction and arrangement of the system, methods, and devices as shown in the various examples of embodiments is illustrative only. Although only a few embodiments have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter recited. For example, elements shown as integrally formed may be constructed of multiple parts or elements show as multiple parts may be integrally formed, the operation of the interfaces may be reversed or otherwise varied, the length or width of the structures and/or members or connector or other elements of the system may be varied, the nature or number of adjustment positions provided between the elements may be varied (e.g. by variations in the number of engagement slots or size of the engagement slots or type of engagement). The order or sequence of any process or method steps may be varied or re-sequenced according to alternative embodiments. Other substitutions, modifications, changes and omissions may be made in the design, operating conditions and arrangement of the various examples of embodiments without departing from the spirit or scope of the present inventions.

While this invention has been described in conjunction with the examples of embodiments outlined above, various alternatives, modifications, variations, improvements and/or substantial equivalents, whether known or that are or may be presently foreseen, may become apparent to those having at least ordinary skill in the art. Accordingly, the examples of embodiments of the invention, as set forth above, are intended to be illustrative, not limiting. Various changes may be made without departing from the spirit or scope of the invention. Therefore, the invention is intended to embrace all known or earlier developed alternatives, modifications, variations, improvements and/or substantial equivalents.

The technical effects and technical problems in the specification are exemplary and are not limiting. It should be noted that the embodiments described in the specification may have other technical effects and can solve other technical problems.

1. A coating apparatus for applying a film to a substrate comprising:
a coating chamber;
a filament fixture having a filament array;
a tensioning device to maintain tension on the filament array to maintain filaments in a planar array during the application or removal of heat or current to the filaments; and
a stage arranged to hold the substrate to be treated in the coating apparatus in proximity to the filament array.

2. The coating apparatus of claim 1, wherein the apparatus is adapted for hot filament chemical vapor deposition.

3. The coating apparatus of claim 1, wherein the apparatus is adapted for carbon-ion implantation.

4. The coating apparatus of claim 1, wherein the coating chamber comprises a gas inlet aligned with the filament array such that gas may be passed over a filament in the filament array.

5. The coating apparatus of claim 1, wherein the filament fixture further comprises the tensioning device for tensioning the filament array, and one or more electrodes electrically coupling one or more filaments.

6. The coating apparatus of claim 5, wherein an electrode from the plurality of electrodes is a movable electrode coupled to the tensioning device.

7. The coating apparatus of claim 6, wherein the moveable electrode is movable in a linear motion.

8. The coating apparatus of claim 1, wherein the tensioning device dynamically adjusts filament tension based upon a variable to maintain the planar array.

9. The coating apparatus of claim 1, wherein the apparatus maintains a constant thermal gradient across the substrate to be treated.

10. The coating apparatus of claim 1, wherein the stage is a movable stage which dynamically positions the substrate in proximity to the filament array so as to maintain a constant thermal gradient across the substrate.

11. The coating apparatus of claim 10, further comprising a device for monitoring temperature which device is in communication with the movable stage, wherein the position of the movable stage is dynamically adjusted in response to a monitored temperature.

12. The coating apparatus of claim 10, wherein the distance between the movable stage and the filament array is dynamically adjustable throughout and between processing steps.

13. The coating apparatus of claim 10, wherein the movable stage is movable away from the filament array during non-optimal processing conditions.

14. The coating apparatus of claim 1, wherein the filament array has a stabilizing chute wire.

15. The coating apparatus of claim 14, wherein the filament array has stabilizing chute wires at first and second ends of the array.

16. The coating apparatus of claim 1, further comprising a control system operably coupled to the coating apparatus for controlling one or more variables.

17. An assembly for applying a film to a substrate comprising a filament array having a plurality of filaments coupled to a moveable electrode and a stationary electrode, a tensioning device coupled to the moveable electrode for movement in of the moveable electrode in a linear motion to maintain tension on the filament array and maintain the planar array based upon a variable, and a movable stage arranged to hold the substrate to be treated in the coating apparatus a distance from the filament array based upon maintaining a constant thermal gradient across the substrates being treated in the apparatus.

18. The assembly of claim 17, wherein the tensioning device maintains constant filament tension during the application of current.

19. The assembly of claim 17, wherein the position of the movable stage is adjustable in response to temperature.

20. The assembly of claim 17, wherein the filament array has a stabilizing chute wire.

21. The assembly of claim 17, further comprising a control system operably coupled to the coating apparatus for controlling one or more variables.

22. An apparatus for applying nanocrystalline diamond to a substrate comprising:
a coating chamber comprising a sealed pressure chamber having an interior cavity;
a filament fixture in the interior cavity of the coating chamber having a filament array, a tensioning device to maintain tension on the filament array, a moveable electrode coupled to the tensioning device and to the filament array, and a stationary electrode coupled to the filament array;
a gas inlet on the coating chamber aligned with the filament array such that a gas may be introduced and passed over a filament in the filament array; and
a movable stage arranged to hold the substrate to be treated in the apparatus in proximity to the filament array.

23. The apparatus of claim 22, wherein the tensioning device dynamically adjusts filament tension based upon a variable to maintain a planar array.

24. The apparatus of claim 23, wherein the tensioning device maintains constant filament tension during the application of current to the electrodes.

25. The apparatus of claim 22, wherein a constant thermal gradient across the substrate to be treated is maintained.

26. The apparatus of claim 25, wherein the position of the movable stage is dynamically adjusted in response to a temperature to maintain the thermal gradient across the substrates being treated in the apparatus.

27. The apparatus of claim 22, further comprising a control system operably coupled to the apparatus for controlling one or more variables.

28. A coating apparatus for applying a film to a substrate comprising:
a coating chamber;
a filament fixture having a three-dimensional filament array, wherein multiple single planar arrays are positioned in a stacked manner;
a tensioning device to maintain tension on the filament array to maintain filaments in the single planar arrays during the application or removal of heat to the filaments; and
a stage arranged to hold the substrate to be treated in the coating apparatus in proximity to the three dimensional filament array.

29. The coating apparatus of claim 28, wherein a first planar array of filaments is provided in a first direction on or in a first plane, and a second planar array of filaments is provided in a second direction on or in a second plane.

30. The coating apparatus of claim 29, wherein the second planar array of filaments is arranged perpendicular to the first planar array of filaments.

31. The coating apparatus of claim 28, wherein the first planar array of filaments and the second planar array of filaments are carried by electrodes.
